(19) United States
(12) Patent Application Publication
(10) Pub. No.: US 2008/0316929 A1
(43) Pub. Date: Dec. 25, 2008

(54) Method and Network Element for Guaranteeing a Quality of Service in a Decentralized Network

(75) Inventors: Jens-Uwe Busser, Munchen (DE); Markus Bohm, Munchen (DE); Michael Finkenzeller, Munchen (DE); Gerald Liebe, Strausberg (DE)

Correspondence Address: BELL, BOYD & LLOYD, LLP, P.O. BOX 1135, CHICAGO, IL, 60690, US

(73) Assignee: Nokia Siemens Networks GmbH & Co. KG, Munich (DE)

(21) Appl. No.: 11/884,062

(22) PCT Filed: Feb. 7, 2006
(86) PCT No.: PCT/EP06/50724

§ 371 Date: Aug. 20, 2008

(30) Foreign Application Priority Data
Feb. 9, 2005 (DE) 10 2005 005 898.1

(51) Int. Cl. G01R 31/08; H04L 12/28

(52) U.S. Cl. 370/235; 370/400

(57) ABSTRACT

A guaranteeing a quality of service in a decentralized network, wherein at least one first network element at least temporarily provides a service for at least one second network element is provided. The parameters relevant for the quality of service are provided via an authentication of the first network element.

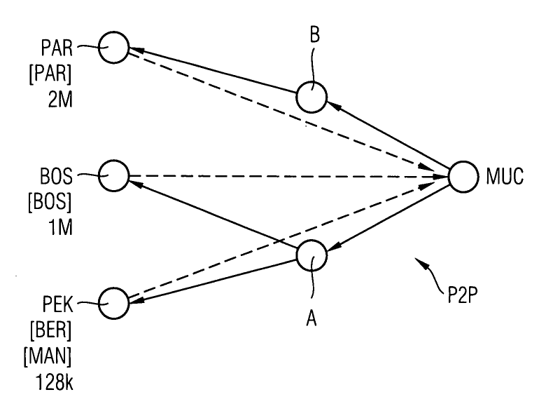

The invention relates to a method for guaranteeing a quality of service in a decentralized network according to the preamble of claim 1 and to a network element according to the preamble of claim 6.

In the prior art, decentralized networks are known in which an overwhelming proportion of connected network elements can offer functions and services to other network elements and can on the other hand use functions and services offered by other network elements, without a central controlling instance having to be provided for this purpose. In other words, a network element under consideration assumes ad hoc a role as server or a role as client relative to another network element. A network element connected to the decentralized network is, to distinguish it from a normal client-server arrangement, often also called a “peer”. Consequently, such decentralized networks are also called peer-to-peer networks, or P2P networks for short.

The conceptual definition of a decentralized network does not in other respects generally exclude the presence of central instances. The designation decentralized network, or P2P network, is used also to refer to hybrid forms of networks in which certain tasks are transferred to a central instance or server, insofar as in these networks no server is provided via which each and every communication link between two network elements has to be routed.

In decentralized networks, services are provided not by central instances but between individual network elements. The network elements carry out e.g. access controls and report charging for the services used to central servers.

In a network of the type stated, resources are stored in a decentralized manner on those network elements whose index value, i.e. for example a “hash value” formed from an IP (Internet Protocol) address and a port number of the network element best match the index value of the resource (e.g. hash value of a search term, etc.).

In today's networks, the guaranteeing of a quality of service, also often referred to among experts as QoS, has not yet been universally achieved.

While methods are known which are based on marking with a priority level, the consequence of which is that data marked in this way is preferentially forwarded and processed, this method has the obvious disadvantage that the setting is generally incumbent upon the communicating subscriber, who out of self-interest tends to assess the priority of his data transmission as being higher than the majority of other subscribers would. In addition, only one data throughput that has been reserved in advance is usually permitted between network boundaries, in order to design network capacity utilization in a manner that is plannable and geared toward optimal throughput.

In decentralized networks, the network structure depends on the subscribing network nodes. The structures are changed to a certain extent by newly arriving and departing nodes. Guaranteeing a quality of service in decentralized networks is therefore even more difficult than in networks based upon a server-client principle and has not as yet been achieved in the prior art.

An object of the invention is therefore to indicate means for guaranteeing a quality of service in decentralized networks.

The object is achieved in a communication system as specified in claim 1 with a method comprising the features of claim 1, and with regard to its device aspect in a network element comprising the features of claim 7. The object is also achieved in a computer program product comprising the features of claim 11.

In a method for guaranteeing a quality of service in a decentralized network, in which at least one first network element provides at least temporarily a service for at least one second network element, the invention provides that parameters relevant for the quality of service are provided in authentication means of the first network element.

A substantial advantage of the method according to the invention is that parameters relevant for the quality of service in an individual network element are assigned to authentication means and therefore are not accessible to any manipulation by the subscriber operating the respective network element. Such manipulation was, prior to the time rank of the solution proposed here, a frequently encountered means of feigning a higher quality of service and thereby achieving without justification a profit of enhanced privileges through increased data traffic or increased charging.

Since the network element proposed according to the invention is a network element which otherwise functions in a usual manner and hierarchy, advantageously no changes in the architecture of the network and no major interventions in the software of the network element are necessary in order to implement the method according to the invention.

Advantageous further developments of the invention will be indicated in the subclaims.

An exemplary embodiment with further advantages and configurations of the invention will be explained in detail below with reference to the drawing.

The FIGURE shows a structogram for the schematic representation of a decentralized network.

A decentralized network P2P comprises a second network element MUC which would like to use a service of at least one first network element PAR, BOS, PEK. Each of the aforementioned network elements MUC; PAR, BOS, PEK. optionally provides a certificate (not shown).

A connection to one or more of the first network elements PAR, BOS, PEK is effected e.g. via intermediary nodes A, B, which are configured for example as network elements or peers A, B or else take on fully or in part functions of a layer 3 network element A, B or router A, B. It is assumed that the second network element MUC is located in Munich.

It is assumed that a group of first network elements PAR, BOS, PEK comprises a network element PAR located in Paris, a network element BOS located in Boston and a network element PEK located in Peking. The reference characters of the second network element MUC and of the first network elements PAR, BOS, PEK thus symbolize the abbreviated actual geographical location in which the network elements MUC; PAR, BOS, PEK are physically deployed.

Below the respective reference character of the group of first network elements PAR, BOS, PEK a reference character noted in square brackets symbolizes the respective geographical location [PAR], [BOS]; [BER], [MAN] “alleged” by the respective network element PAR, BOS, PEK. The alleged geographical location [PAR], [BOS]; [BER], [MAN] is understood to be the location which the respective first network element PAR, BOS, PEK alleges as its geographical location to network elements MUC seeking services. In the case of the network elements PAR; BOS located in Paris and Boston, the alleged location [PAR]; [BOS] matches their actual location PAR; BOS. It is assumed that the network element PEK which is actually located in Peking however alleges in the scenarios that follow a false location to the network element MUC that is seeking a service, namely in a first scenario that it is a network element [BER] based in Berlin and in a second scenario that it is a network element [MAN] based in Manhattan.

Below the alleged geographical location [PAR], [BOS]; [BER], [MAN] a further reference character 2 M, 1 M; 128K symbolizes a bandwidth 2M, 1 M; 128 k alleged by the respective network element PAR, BOS, PEK as being the maximum achievable for a data transmission, i.e. in this series 2 Mbit/s, 1 Mbit/s and 128 kbit/s. The aforementioned difference between a mere “alleged” value and a realistic value also applies to this quality-of-service feature.

The alleged geographical location [PAR], [BOS]; [BER], [MAN] and the alleged maximum bandwidth achievable for a data transmission 2 M, 1 M; 128 k stand in this exemplary embodiment for a selection of parameters relevant for a quality of service, which parameters are communicated to the service-seeking network element MUC and with the aid of which a selection of a single or else of a group of service-providing network elements PAR; BOS; PEK is selected.

Of course, in accordance with the decentralized nature of the network P2P, an assignment of the service-seeking network element MUC to the service-providing network elements PAR, BOS, PEK is not predetermined but is carried out in a usual manner by identifying a peer that is appropriate for the service to be provided in the respective case.

It is assumed in the exemplary embodiment that in respect of a service to be provided the group of first network elements PAR, BOS, PEK shown is eligible, a single service-providing network element PAR, BOS, PEK then being selected from this group at the same time or subsequently with the aid of the parameters relevant for the quality of service.

The means according to the invention are based upon the idea that information for authenticating the service-providing network element PAR, BOS, PEK is used in order thereby to guarantee that the fastest or shortest connection is used for utilizing the service. A plurality of network elements PAR, BOS, PEK are in a position to offer a certain service, e.g. the provision of a file or a voice service, in particular a real-time communication link provided by a gateway service from a calling subscriber on the service-seeking network element MUC over the packet-oriented decentralized network P2P to a time-slot-oriented communication network (not shown).

In a first scenario, a user of the service-seeking network element MUC would like to download a file urgently within a limited period. The selection criteria for the service-providing network element to be sought thus cover network elements which have a very wide-bandwidth connection to the decentralized network P2P and can consequently offer a high data throughput as far as the service-seeking network element. A charge to be paid for the service requested constitutes a further criterion in many cases, but in the presented first scenario this is, on account of the urgency, secondary to a high data throughput.

In the search for the desired file, the first network element MUC finds for example five to ten peers having the desired file available.

In contemporary decentralized networks P2P, a file is usually obtained or downloaded without paying charges, as the necessary means for making small charges—e.g. 5 percent per file—has not yet been established.

Each operator of the five to ten peers found now strives for the desired file to be obtained from his peer and therefore alleges particularly good conditions so as to prompt the operator of the first network element MUC to select his own peer manually or automatically.

This alleging or feigning of parameters relevant for the quality of service, in this case a maximum data throughput, is to the detriment of the user on the service-seeking network element MUC.

Through the inventive use of authentication means, e.g. certificates, an inalterability and transparency of the parameters relevant for the quality of service are now achieved. The service-seeking network element MUC contains secure information as to the country and city in which the service-providing network element PAR, BOS, PEK is located, what availability and bandwidth a network connection to this service-providing network element PAR, BOS, PEK has, and so on.

Authentication means procured by the service-providing network elements PAR, BOS, PEK guarantee that the parameters contained are authentic. A subscriber on the service-seeking network element MUC can now decide which of the service-providing network elements PAR, BOS, PEK most advantageously fulfils his requirements in terms of the quality of service or the charges for obtaining the desired file.

Since the subscriber on the service-seeking network element MUC is in this first scenario interested in very short transmission times, he selects in the present case for example a network element which is located geographically near and which offers a high data throughput, for example the network element PAR located in Paris with a data throughput of 2 Mbit/s.

The advantage of the inventive method according to this first scenario will be explained with reference to the FIGURE. Assuming that the service-providing network element PEK located in Peking alleges without applying the inventive method an-inappropriate-location [BER] in Berlin and/or a higher than the achievable data transmission bandwidth of 128 k, a requested download service for a file to be obtained would result in the service-providing network element PEK located in Peking being selected as the network element most closely located geographically and the most suitable in terms of bandwidth.

Applying the inventive method, on the other hand, the geographical location is provided in the authentication means of the service-providing network element PEK and is not accessible to manipulation. The choice in this case will fall to the network element PAR located in Paris, since this has the highest available bandwidth 2 M.

A second scenario relates to a provision of a gateway by one of the service-providing network elements PAR, BOS, PEK in order to establish a communication link from the service-seeking network element MUC over the packet-oriented decentralized network P2P to a time-slot-oriented communication network (not shown).

The operator of the service-seeking network element MUC prefers in this scenario therefore a service-providing network element PAR, BOS, PEK with a gateway functionality which is preferably located in the local area network or at least close to the local area network in which a subscriber to be called by means of this communication link is located.

In this scenario, too, the use according to the invention of the parameters relevant for the quality of service in the authentication means guarantees that the gateway is actually located at the location which is contained in the parameters relevant for the quality of service, so for the calling subscriber on the service-seeking network element MUC preferably only charges for local calls have to be paid. The quality of service sought thus corresponds in this scenario to proximity to the destination location of the subscriber to be called.

The advantage of the inventive method according to this second scenario will be explained with the reference of the FIGURE. Assuming that the service-providing network element PEK located in Peking alleges without applying the inventive method an-inappropriate-location [MAN] in Manhattan, a requested gateway service for a subscriber to be called in New York City would result in the service-providing network element PEK located in Peking being selected as the geographically most closely located network element PEK. Applying the inventive method, on the other hand, the geographical location is provided in the authentication means of the service-providing network element PEK and is not accessible to manipulation. The choice for execution of the gateway service will in this case fall to the network element BOS located in Boston.

Furthermore, a high quality of the voice service used can be guaranteed through a larger bandwidth.

The inclusion of parameters characterizing the quality of service in the authentication means can also guarantee a secure quality of service for peer-to-peer networks P2P. Such authentication means can be provided e.g. by certificates and checked by appropriate signing of messages.

Depending on the quality of service a corresponding charge can be demanded from the user by service-providing peers.

The provision of parameters characterizing the quality of service in the authentication means is in one configuration of the means according to the invention implemented only for the service-providing network elements PAR, BOS, PEK. For service-seeking network elements MUC—including for example “mobile” network elements that provide a wireless data transmission via an air interface—these specific authentication features are not used in this configuration.

The method indicated guarantees that the quality of service transmitted to the service-seeking peer is also actually available and that a service-seeking peer is not misled by feigned quality-of-service parameters of a service-providing peer. Furthermore, acceptance of the peer-to-peer network P2P is enhanced by this means.

1.-10. (canceled)

11. A method for guaranteeing a quality of service in a decentralized network, comprising:
providing at least temporarily a service for at least one second network element by at least one first network element; and
providing parameters relevant for the quality of service via an authentication of the first network element.

12. The method as claimed in claim 11, wherein the parameters relevant for the quality of service include a geographical location of the first network element.

13. The method as claimed in claim 11, wherein the parameters relevant for the quality of service include a bandwidth for at least one network access available for the first network element.

14. The method as claimed in claim 11, wherein the authentication is configured in a certificate-protected manner.

15. The method as claimed in claim 11, wherein the authentication is included in a certificate issued by a certification authority.

16. The method as claimed in claim 11, wherein the decentralized network is a peer-to-peer network.

17. A network element in a decentralized network that is a peer-to-peer network, comprising:
a service provided at least temporarily for at least one second network element; and
an authentication having at least one parameter relevant for the quality of service.

18. The network element as claimed in claim 16, wherein the at least one parameter relevant for the quality of service includes a geographical location of the first network element and a bandwidth for at least one network access available for the first network element.

19. The network element as claimed in claim 17, further comprises a certificate protection of the authentication.

20. The network element as claimed in claim 17, wherein the authentication is a certificate issued by a certification authority.

21. A computer program product stored on a computer readable memory and when executed on the computer comprises the steps of:
providing at least temporarily a service for at least one second network element by at least one first network element; and
providing parameters relevant for the quality of service via an authentication of the first network element,
wherein the parameters relevant for the quality of service include a geographical location of the first network element and a bandwidth for at least one network access available for the first network element, and
wherein the network is a peer-to-peer network.
